(19) United States
(12) Patent Application Publication
(10) Pub. No.: US 2025/0391633 A1
(43) Pub. Date: Dec. 25, 2025

(54) ION EXTRACTION OPTICS WITH DYNAMIC EXTRACTION ANGLE CONTROL

(71) Applicant: Applied Materials, Inc., Santa Clara, CA (US)

(72) Inventors: Thomas James SOLDI, Somerville, MA (US); Daniel DISTASO, Rowley, MA (US)

(73) Assignee: Applied Materials, Inc., Santa Clara, CA (US)

(21) Appl. No.: 18/753,674

(22) Filed: Jun. 25, 2024

(51) Int. Cl. H01J 37/30; H01J 37/317; H01J 37/32

(52) U.S. Cl. CPC H01J 37/3007; H01J 37/3171; H01J 37/32412; H01J 2237/0435; H01J 2237/1502; H01J 2237/30472

(57) ABSTRACT

An ion extraction optics for extracting a plurality of ion beams includes an extraction plate defining an extraction aperture, and a beam blocker located adjacent the extraction aperture and mounted to the extraction plate by a first actuator and a second actuator, wherein the beam blocker and the extraction aperture define a first extraction slit and a second extraction slit, and wherein the first actuator and the second actuator are adapted to move the beam blocker relative to the extraction plate.

### FIELD OF THE DISCLOSURE

Embodiments of the present disclosure relate generally to the field of ion beam processing apparatus, and more particularly to improved extraction optics for facilitating dynamic control of ion beam extraction angles.

### BACKGROUND OF THE DISCLOSURE

Known apparatus used to treat substrates with ions include beamline ion implanters and plasma immersion ion implantation tools. These approaches are appropriate for implanting ions over a range of energies. In beamline ion implanters, ions are extracted from a source, are mass analyzed, and are then transported to a substrate surface. In plasma immersion ion implantation apparatus, a substrate is located in the same chamber where the plasma is generated, adjacent the plasma. The substrate is set at negative potential with respect to the plasma, and ions crossing a plasma sheath in front of the substrate impinge on the substrate at a perpendicular angle of incidence.

Recently, a new ion beam processing apparatus facilitating control of extracted ion angular distribution (IAD) has been developed. In this apparatus, ion beams are extracted from a plasma chamber and are directed at a substrate disposed in a process chamber adjacent the plasma chamber. The ion beams are extracted through extraction slits of special geometry defined by an ion extraction optics proximate a plasma in the plasma chamber, wherein the ion beams are extracted at angles (“extraction angles”) dictated by curvatures of plasma sheaths formed at the extraction slits.

In some cases, process recipes implemented in processing apparatus are dynamically changed to obtain ion beams with desired characteristics. For example, process parameters such radio frequency (RF) power, source pressure, gas flow, extraction voltage, etc. can be adjusted on the fly to fine-tune characteristics of the plasma and the extracted ion beams. However, varying the aforementioned process parameters generally results in changes in plasma density and electric field, which in turn alter the curvatures of the plasma sheaths at the extraction slits and change the extraction angles of the ion beams extracted therethrough. Thus, it is generally not possible to modify a process recipe without affecting the extraction angles of the ion beams. In order to change the extraction angles of the ion beams independently of the process recipe, a processing apparatus is typically shut down (e.g., powered down and vented) and the hardware of the ion extraction optics is changed to obtain the desired extraction angles. Modifying the processing apparatus in the manner is associated with significant downtime, reduced throughput, and additional hardware costs.

With respect to these and other considerations, the present disclosure is provided.

### SUMMARY

This Summary is provided to introduce a selection of concepts in a simplified form further described below in the Detailed Description. This Summary is not intended to identify key features or essential features of the claimed subject matter, nor is the summary intended as an aid in determining the scope of the claimed subject matter.

An ion extraction optics for extracting a plurality of ion beams in accordance with the present disclosure may include an extraction plate defining an extraction aperture, and a beam blocker located adjacent the extraction aperture and mounted to the extraction plate by a first actuator and a second actuator, wherein the beam blocker and the extraction aperture define a first extraction slit and a second extraction slit, and wherein the first actuator and the second actuator are adapted to move the beam blocker relative to the extraction plate.

A processing apparatus in accordance with an embodiment of the present disclosure may include a plasma chamber adapted to contain a plasma, a process chamber located adjacent the plasma chamber and adapted to contain a substrate for processing, and an ion extraction optics located between the plasma chamber and the process chamber and adapted to extract a plurality of ion beams from the plasma chamber and to direct the plurality of ion beams into the process chamber, the ion extraction optics including an extraction plate defining an extraction aperture, and a beam blocker located adjacent the extraction aperture and mounted to the extraction plate by a first actuator and a second actuator, wherein the beam blocker and the extraction aperture define a first extraction slit and a second extraction slit, and wherein the first actuator and the second actuator are adapted to move the beam blocker relative to the extraction plate.

### BRIEF DESCRIPTION OF THE DRAWINGS

By way of example, various embodiments of the disclosed techniques will now be described, with reference to the accompanying drawings, wherein:

FIG. 1 is a schematic cross-sectional view illustrating a processing apparatus in accordance with an embodiment of the present disclosure;

FIG. 2A is a rear view illustrating an ion extraction optics of the processing apparatus shown in FIG. 1;

FIG. 2B is a right-side cross-sectional view illustrating the ion extraction optics shown in FIG. 2A;

FIG. 2C is a perspective cutaway view illustrating the ion extraction optics shown in FIG. 2A and the process chamber of the processing apparatus shown in FIG. 1;

FIG. 3A is a right-side cross-sectional view illustrating the ion extraction optics of the present disclosure with a beam blocker of the ion extraction optics in a first position;

FIG. 3B is a right-side cross-sectional view illustrating the ion extraction optics of the present disclosure with a beam blocker of the ion extraction optics in a second position;

FIG. 4 is a bottom view illustrating the ion extraction optics of the present disclosure;

FIG. 5 is a rear view illustrating another ion extraction optics in accordance with an embodiment of the present disclosure.

### DETAILED DESCRIPTION

The embodiments described herein provide ion beam processing apparatus capable of dynamically changing ion beam extraction angles independently of changes to a process recipe. More particularly, the present embodiments provide a novel ion extraction optics including a dynamically adjustable beam blocker.

As used herein, the term “extraction angle” may refer to the mean angle of a group of ions of an ion beam exiting an extraction slit relative to a line extending perpendicularly from a front surface of an extraction plate toward a substrate (as further described below). In the embodiments disclosed herein, the novel ion extraction optics may facilitate dynamic adjustment of ion beam extraction angles in an ion beam processing apparatus. Such adjustment is independent of a process recipe implemented in the ion beam processing apparatus and can be made dynamically while performing a process on a substrate, without requiring the ion beam processing apparatus to be shut down (e.g., powered down and vented) or disassembled to alter hardware configurations.

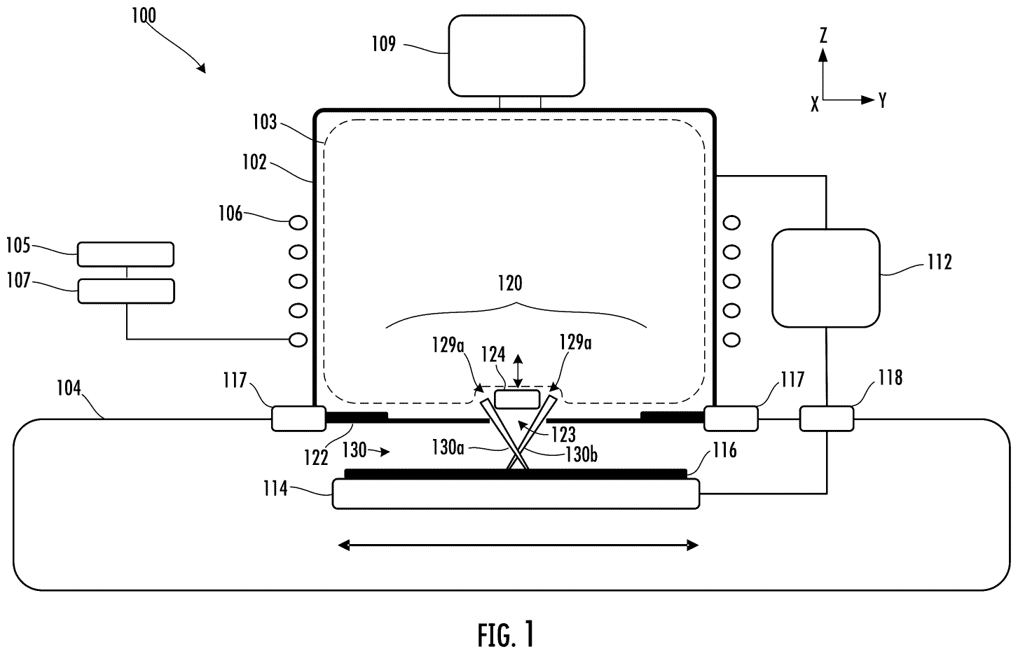

FIG. 1 depicts an ion beam processing apparatus 100 (hereinafter “the processing apparatus 100”) in accordance with embodiments of this disclosure. The processing apparatus 100 may include a plasma source comprised of a plasma chamber 102 to generate a plasma 103. The plasma chamber 102 may function as part of a plasma source such as a RF inductively-coupled plasma (ICP) source, a capacitively coupled plasma (CCP) source, a helicon source, an electron cyclotron resonance (ECR) source, an indirectly heated cathode (IHC) source, a glow discharge source, or other plasma sources known to those skilled in the art. In the embodiment illustrated in FIG. 1, the plasma source is an ICP source, where power from an RF generator 105 is coupled into the plasma through an RF matching network 107. The transfer of the RF power from the RF generator 105 to the gas atoms and/or molecules takes places through an antenna 106 and a dielectric window (not shown). A gas manifold 109 may be connected to the plasma chamber 102 through appropriate gas lines and gas inlets. The plasma chamber 102 and/or an adjacent process chamber 104 also may be connected to a vacuum system (not shown), such as a turbo molecular pump backed by a rotary or membrane pump. The plasma chamber 102 may be defined by adjoining chamber walls and may be electrically insulated by insulators 117. The process chamber 104 may include a substrate holder 114 for supporting a substrate 116. The plasma chamber 102 may be biased with respect to the substrate holder 114 and the process chamber 104 using a bias voltage supply 112. For example, the plasma chamber 102 may be held at elevated voltage, such as +1000 V, while the substrate holder 114, substrate 116, and process chamber 104 are grounded. Alternatively, the substrate holder 114 may be held at negative potential, while the plasma chamber 102 is grounded. Electrical connection between the bias voltage supply 112 and the substrate holder 114 may be accomplished through an electrical feedthrough 118. In these scenarios, positive ions may be extracted from the plasma 103 and directed to the substrate 116 at an ion energy proportionate to the difference in voltage between the plasma chamber 102 and the substrate holder 114.

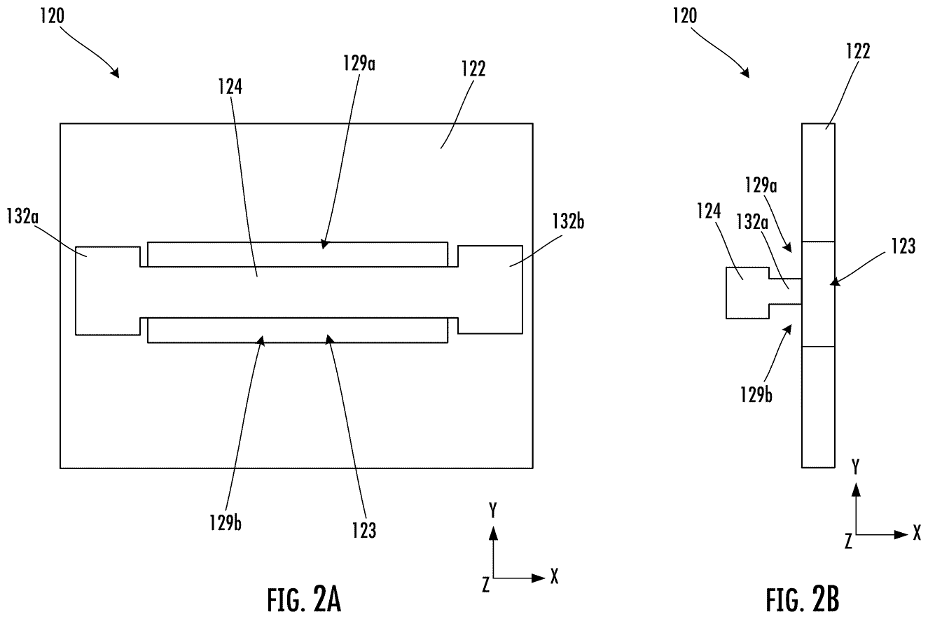

An ion extraction optics 120 may be arranged along a side of the plasma chamber 102. In FIG. 1, the ion extraction optics 120 is arranged at the bottom of the plasma chamber 102, extending in a horizontal plane. This orientation is presented for purposes of illustration and is not intended to be limiting. In other views, such as in FIGS. 2A and 2B, the ion extraction optics 120 is reoriented (i.e., rotated relative to FIG. 1) such that the ion extraction optics 120 extends in a vertical plane. The present disclosure is not limited in this regard. The ion extraction optics 120 may be disposed between the plasma chamber 102 and the process chamber 104. The ion extraction optics 120 may define a portion of a chamber wall of the plasma chamber 102 or the process chamber 104 or both, in some instances. The ion extraction optics 120 defines apertures through which ions may be extracted as angled ion beams and directed toward the substrate 116 as further described below.

In various embodiments, and as detailed below, the ion extraction optics 120 may include various components defining a plurality of ion beams. For example, the ion extraction optics 120 may define a plurality of extraction slits, elongated along the x-dimension of the illustrated Cartesian coordinate system (i.e., into the plane of the page in FIG. 1). These extraction slits may define a plurality of ribbon beams, elongated in the x-dimension and having designed properties, such as ion energy, ion current density, etc.

In various embodiments, the substrate holder 114 may be coupled to a drive (not shown) configured to move the substrate holder 114 along a direction parallel to the y-axis of the illustrated Cartesian coordinate system. In further embodiments, the substrate holder 114 may be movable along a direction parallel to the x-axis, z-axis, or both. This movement provides the processing apparatus 100 with two degrees of freedom, i.e., allows relative position of the substrate vs an extraction aperture to be modified and allows the substrate 116 to be scanned with respect to an aperture so ions may be provided over the entire surface of substrate 116 in some instances. In various embodiments, the substrate holder 114 may be rotatable around the z-axis in small increments, such as increments of 1 degree, so process uniformity can be further improved.

As further illustrated in FIG. 1, the ion extraction optics 120 may include an extraction plate 122 defining an extraction aperture 123. The ion extraction optics 120 may further include a beam blocker 124 arranged proximate the extraction aperture 123. The extraction aperture 123 and the beam blocker 124 may together define first and second extraction slits 129a, 129b located on opposing sides of the beam blocker 124, between the beam blocker 124 and the extraction plate 122. The first and second extraction slits 129a, 129b provide an opening for respective first and second ion beams 130a, 130b to pass therethrough.

Referring now to FIGS. 2A and 2B, a rear view and a side cross-sectional view illustrating the ion extraction optics 120 of the processing apparatus 100 (see FIG. 1) of the present disclosure in isolation are shown, respectively. The rear view shown in FIG. 2A is taken from a vantage point within the plasma chamber 106 looking toward the substate 116 (see FIG. 1). FIG. 2C illustrates a perspective cutaway showing the relationship between the plasma chamber 106 and the ion extraction optics 120. As described above, the ion extraction optics 120 may include an extraction plate 122 defining an extraction aperture 123. The ion extraction optics 120 may further include a beam blocker 124 arranged proximate the extraction aperture 123 and coupled to the extraction plate 122 by first and second actuators 132a, 132b on opposing lateral sides of the extraction aperture 123. The beam blocker 124 may effectively bifurcate the extraction aperture 123 to define laterally elongated first and second extraction slits 129a, 129b (i.e., elongated along the x-dimension of the illustrated Cartesian coordinate system). The first and second actuators 132a, 132b may be adapted to controllably move the beam blocker 124 toward and away from the extraction plate 122 along the z-dimension of the illustrated Cartesian coordinate system (i.e., along a dimension perpendicular to a rear surface of the extraction plate 122) as further described below. The first and second actuators 132a, 132b may be any type of actuators suitable for controllably moving the beam blocker 124 in the aforementioned manner. For example, in various embodiments, the first and second actuators 132a, 132b may be linear actuators, servo motors, or the like, adapted to extend and retract and retract (e.g., in a telescoping manner) to move the beam blocker 124 along the z-dimension of the illustrated Cartesian coordinate system. In some embodiments, the first and second actuators 132a, 132b may also be adapted to move the beam blocker 124, along the y-dimension of the illustrated Cartesian coordinate system. The present disclosure is not limited in this regard.

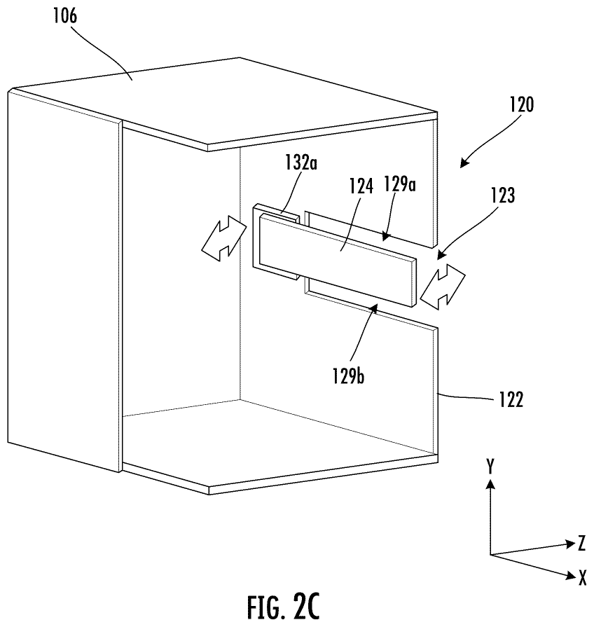

By operating the first and second actuators 132a, 132b (e.g., via a user interface/controller of the processing apparatus 100, not separately shown) to adjust the position of the beam blocker 124 relative to the extraction plate 122, the shapes of plasma sheaths (also referred to a plasma menisci) at the first and second extraction slits 129a, 129b can be modified to manipulate the extraction angles of ion beams extracted therethrough. For example, referring to FIG. 3A, the first and second actuators 132a, 132b have been adjusted to hold the beam blocker 124 a first distance d1 from a rear of the extraction plate 122, wherein d1 is measured along the z-dimension of the illustrated Cartesian coordinate system (only the first actuator 132a is shown in FIG. 3A). At this distance, first and second plasma sheaths 131a, 131b formed at the first and second extraction slits 129a, 129b during operation of the processing apparatus 100 (see FIG. 1) may exhibit convex curvatures (i.e., presenting convex curvatures to the extraction aperture 123), causing the first and second ion beams 130a, 130b to be extracted at a relatively steep first angle α1 relative to a line p extending perpendicularly from a front surface of the extraction plate 122. Referring to FIG. 3B, the first and second actuators 132a, 132b have been adjusted to hold the beam blocker 124 a second distance d2 from a rear of the extraction plate 122, wherein d2 is greater than the distance d1 in FIG. 3A (only the first actuator 132a is shown in FIG. 3B). At this distance, the first and second plasma sheaths 131a, 131b formed at the first and second extraction slits 129a, 129b during operation of the processing apparatus 100 (see FIG. 1) may exhibit concave curvatures (i.e., presenting concave curvatures to the extraction aperture 123), causing the first and second ion beams 130a, 130b to be extracted at a relatively shallow second angle α2 (i.e., shallower than al) relative to a line p extending perpendicularly from a front surface of the extraction plate 122. Thus, by operating the first and second actuators 132a, 132b to change the distance between the beam blocker 124 and the extraction plate 122, the shapes of the first and second plasma sheaths 131a, 131b can be modified to selectively adjust the extractions angles of the first and second ion beams 130a, 130b. Such adjustment can be performed without changing a process recipe implemented in the processing apparatus 100 (see FIG. 1), such process recipe defining process parameters including, and not limited to, radio frequency (RF) power, source pressure, gas flow, extraction voltage, etc.

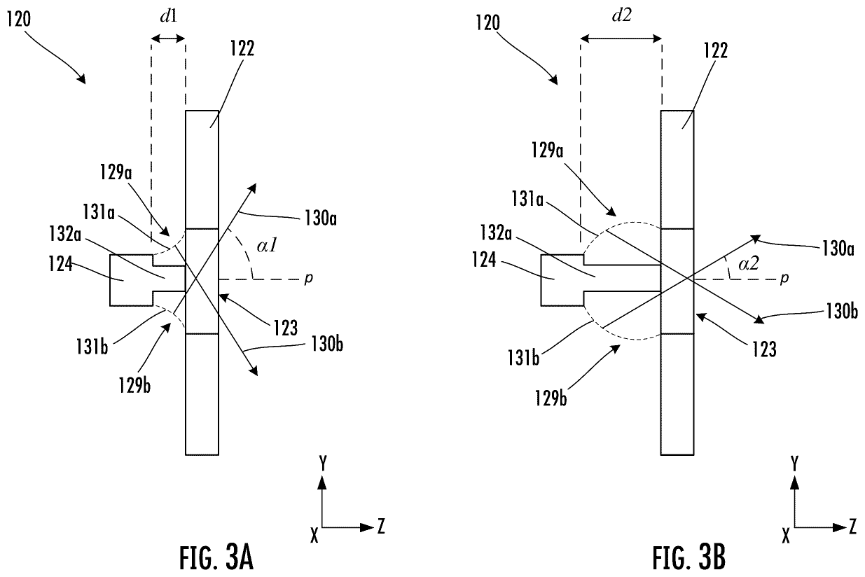

In various embodiments, the first and second actuators 132a, 132b may be operated independently of one another to allow a first end of the beam blocker 124 to be positioned a first distance from the extraction plate 122 while a second end of the beam blocker 124 is positioned a second distance from the extraction plate 122, the second distance being different than the first distance. For example, referring to FIG. 4, the first actuator 132a has been adjusted to hold a first end of the beam blocker 124 a first distance d1 from a rear of the extraction plate 122, while the second actuator 132b has been adjusted to hold a second end of the beam blocker 124 a second distance d2 from a rear of the extraction plate 122. Adjusting the first and second actuators 132a, 132b in this manner (i.e., in an asymmetric manner) may facilitate compensation for intrinsic non-uniformity of beam current across the extraction aperture 123 (i.e., along the x-dimension of the illustrated Cartesian coordinate system) or may allow for the introduction of cross-beam non-uniformity if desired for a particular application. For example, in the configuration shown in FIG. 4, beam current toward the left side of the extraction aperture 123 may be intrinsically higher than beam current toward the right side of the extraction aperture 123 due to conditions within the plasma chamber 102 (see FIG. 1). By moving the second end of the beam blocker 124 further away from the extraction plate 122 than the first end of the beam blocker 124, the beam current toward the right side of the extraction aperture 123 can be increased to match (or nearly match) the beam current toward the left side of the extraction aperture 123.

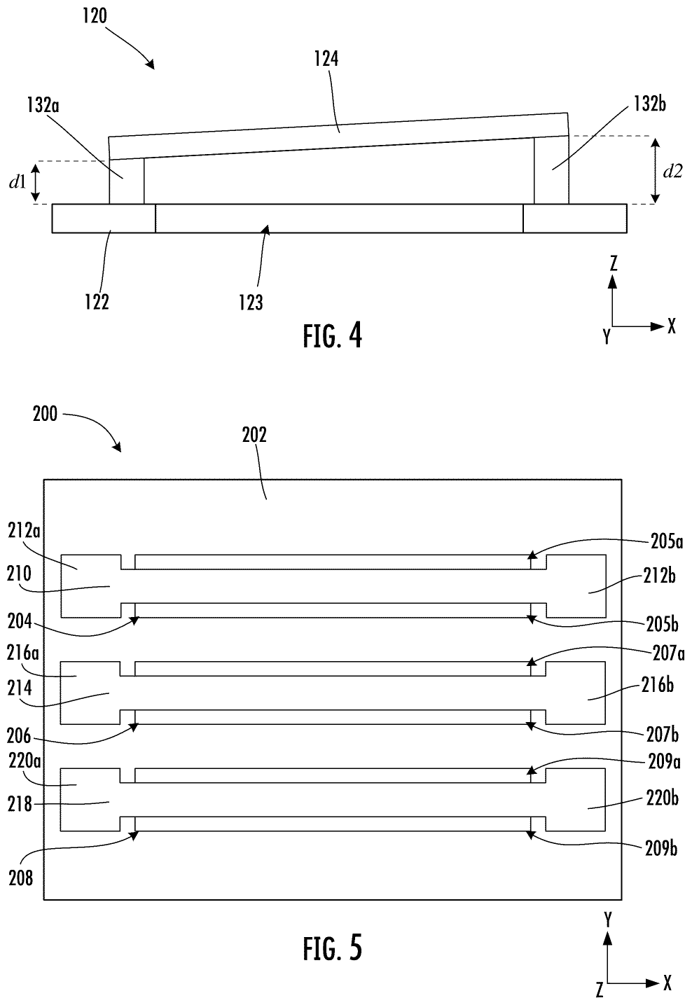

Further embodiments of the present disclosure are contemplated wherein the ion extraction optics may include an extraction plate defining multiple extraction apertures with corresponding beam blockers coupled to corresponding sets of actuators. For example, referring to FIG. 5, an ion extraction optics 200 is shown that includes an extraction plate 202 having a first extraction aperture 204, a second extraction aperture 206, and a third extraction aperture 208 formed therein in a vertically spaced-apart arrangement (i.e., spaced apart along the y-dimension of the illustrated Cartesian coordinate system). A first beam blocker 210 may be arranged proximate the first extraction aperture 204 and may be coupled to the extraction plate 202 by first and second actuators 212a, 212b on opposing lateral sides of the first extraction aperture 204. The first beam blocker 210 may effectively bifurcate the first extraction aperture 204 to define laterally elongated first and second extraction slits 205a, 205b. A second beam blocker 214 may be arranged proximate the second extraction aperture 206 and may be coupled to the extraction plate 202 by third and fourth actuators 216a, 216b on opposing lateral sides of the second extraction aperture 206. The second beam blocker 214 may effectively bifurcate the second extraction aperture 206 to define laterally elongated third and fourth extraction slits 207a, 207b. A third beam blocker 218 may be arranged proximate the third extraction aperture 208 and may be coupled to the extraction plate 202 by fifth and sixth actuators 220a, 220b on opposing lateral sides of the third extraction aperture 208. The third beam blocker 218 may effectively bifurcate the third extraction aperture 208 to define laterally elongated fifth and sixth extraction slits 209a, 209b. The first, second, third, fourth, fifth, and sixth actuators 212a, 212b, 216a, 216b, 220a, 220b may be operated in the manner described above (i.e., with respect to the first and second actuators 132a, 132b) to adjust distances between the first, second, and third beam blockers 210, 214, 218 and the extraction plate 202 to modify the shapes of plasma sheaths formed at the first, second, third, fourth, fifth, and sixth extraction slits 205a, 205b, 207a, 207b, 209a, 209b to dynamically change the extraction angles of ion beams extracted therethrough. The first, second, and third beam blockers 210, 214, 218 may be moved independently of one another to achieve different extraction angles at the respective extraction slits.

Those of skill in the art will appreciate the numerous benefits provided by the above-described configurations. For example, the ion extraction optics 120 of the present disclosure facilitates dynamic adjustment of ion beam extraction angles in an ion beam processing apparatus. Such adjustment is independent of a process recipe implemented in the ion beam processing apparatus, and can be made in real time, while performing a process on a substrate, without requiring the ion beam processing apparatus to be shut down (e.g., powered down and vented) or disassembled. Thus, downtime associated with shutting down a processing apparatus to swap out ion extraction optics may be eliminated and throughput may be increased.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, while the present disclosure has been described herein in the context of a particular implementation in a particular environment for a particular purpose, those of ordinary skill in the art will recognize its usefulness is not limited thereto. Embodiments of the present disclosure may be beneficially implemented in any number of environments for any number of purposes. Accordingly, the claims set forth below shall be construed in view of the full breadth and spirit of the present disclosure as described herein.

1. An ion extraction optics for extracting a plurality of ion beams, comprising:
an extraction plate defining an extraction aperture; and
a beam blocker located adjacent the extraction aperture and mounted to the extraction plate by a first actuator and a second actuator, wherein the beam blocker and the extraction aperture define a first extraction slit and a second extraction slit; and
wherein the first actuator and the second actuator are adapted to move the beam blocker relative to the extraction plate.

2. The ion extraction optics of claim 1, wherein the first actuator and the second actuator are adapted to move the beam blocker in a direction orthogonal to a rear surface of the extraction plate between a first position, wherein the beam blocker is a first distance from the extraction plate, and a second position, wherein the beam blocker is a second distance from the extraction plate, wherein at the first position the first extraction slit extracts an ion beam at a first extraction angle and wherein at the second position the first extraction slit extracts an ion beam at a second extraction angle different than the first extraction angle.

3. The ion extraction optics of claim 1, wherein the first actuator and the second actuator can be operated to move the beam blocker to change extraction angles of a first ion beam and a second ion beam extracted through the first extraction slit and the second extraction slit, respectively, independent of a process recipe used to produce the first ion beam and the second ion beam.

4. The ion extraction optics of claim 1, wherein the first actuator and the second actuator are further adapted to move the beam blocker in a direction parallel to a rear surface of the extraction plate.

5. The ion extraction optics of claim 1, wherein the first actuator is mounted to the extraction plate on a first lateral side of the extraction aperture and the second actuator is mounted to the extraction plate on a second lateral side of the extraction aperture opposite the first lateral side.

6. The ion extraction optics of claim 1, wherein the first actuator and the second actuator are servo motors.

7. The ion extraction optics of claim 1, wherein the first actuator and the second actuator are linear actuators.

8. The ion extraction optics of claim 1, wherein the first actuator and the second actuator are linear actuators that are independently operable to move a first end of the beam blocker in a direction orthogonal to a rear surface of the extraction plate a first distance from the extraction plate and to move a second end of the beam blocker in the direction orthogonal to the rear surface of the extraction plate a second distance from the extraction plate, wherein the first distance may be different than the second distance.

9. The ion extraction optics of claim 1, wherein the extraction aperture is a first extraction aperture and wherein the beam blocker is a first beam blocker, the extraction plate further defining a second extraction aperture, the ion extraction optics further comprising a second beam blocker located adjacent the second extraction aperture and mounted to the extraction plate by a third actuator and a fourth actuator, wherein the second beam blocker and the second extraction aperture define a third extraction slit and a fourth extraction slit, wherein the third actuator and the fourth actuator are adapted to move the second beam blocker nearer and further from the extraction plate.

10. A processing apparatus comprising:
a plasma chamber adapted to contain a plasma;
a process chamber located adjacent the plasma chamber and adapted to contain a substrate for processing; and
an ion extraction optics located between the plasma chamber and the process chamber and adapted to extract a plurality of ion beams from the plasma chamber and to direct the plurality of ion beams into the process chamber, the ion extraction optics comprising:
an extraction plate defining an extraction aperture; and
a beam blocker located adjacent the extraction aperture and mounted to the extraction plate by a first actuator and a second actuator, wherein the beam blocker and the extraction aperture define a first extraction slit and a second extraction slit; and
wherein the first actuator and the second actuator are adapted to move the beam blocker relative to the extraction plate.

11. The processing apparatus of claim 10, wherein the first actuator and the second actuator are adapted to move the beam blocker between a first position, wherein the beam blocker is a first distance from the extraction plate, and a second position, wherein the beam blocker is a second distance from the extraction plate, wherein at the first position the first extraction slit extracts an ion beam at a first extraction angle and wherein at the second position the first extraction slit extracts an ion beam at a second extraction angle different than the first extraction angle.

12. The processing apparatus of claim 10, wherein the first actuator and the second actuator can be operated to move the beam blocker to change extraction angles of a first ion beam and a second ion beam extracted through the first extraction slit and the second extraction slit, respectively, independent of a process recipe used to produce the first ion beam and the second ion beam.

13. The processing apparatus of claim 10, wherein the first actuator and the second actuator are further adapted to move the beam blocker in a direction parallel to a rear surface of the extraction plate.

14. The processing apparatus of claim 10, wherein the first actuator is mounted to the extraction plate on a first lateral side of the extraction aperture and the second actuator is mounted to the extraction plate on a second lateral side of the extraction aperture opposite the first lateral side.

15. The processing apparatus of claim 10, wherein the first actuator and the second actuator are servo motors.

16. The processing apparatus of claim 10, wherein the first actuator and the second actuator are linear actuators.

17. The processing apparatus of claim 10, wherein the first actuator and the second actuator are linear actuators that are independently operable to move a first end of the beam blocker a first distance from the extraction plate and to move a second end of the beam blocker a second distance from the extraction plate, wherein the first distance may be different than the second distance.

18. The processing apparatus of claim 10, wherein the extraction aperture is a first extraction aperture and wherein the beam blocker is a first beam blocker, the extraction plate further defining a second extraction aperture, the ion extraction optics further comprising a second beam blocker located adjacent the second extraction aperture and mounted to the extraction plate by a third actuator and a fourth actuator, wherein the second beam blocker and the second extraction aperture define a third extraction slit and a fourth extraction slit, wherein the third actuator and the fourth actuator are adapted to move the second beam blocker nearer and further from the extraction plate.
